(19) United States
(12) Patent Application Publication
(10) Pub. No.: US 2025/0329531 A1
(43) Pub. Date: Oct. 23, 2025

(54) SELECTIVE CHEMICAL METHOD FOR CONTACT HOLE SHRINKING

(71) Applicant: Applied Materials, Inc., Santa Clara, CA (US)

(72) Inventors: LIKUN WANG, Cupertino, CA (US); NANCY FUNG, Livermore, CA (US); RUDY WOJTECKI, East Garrison, CA (US); ZEQING SHEN, San Jose, CA (US); ABHIJIT MALLICK, Fremont, CA (US); KASHISH SHARMA, Santa Clara, CA (US); MADHUR SACHAN, Belmont, CA (US)

(21) Appl. No.: 18/639,705

(22) Filed: Apr. 18, 2024

(51) Int. Cl. H01L 21/027

(52) U.S. Cl. CPC H01L 21/027

(57) ABSTRACT

Embodiments disclosed herein include a method for treating a resist layer comprising a patterned feature with a chemical vapor deposition (CVD) process. In an embodiment, the CVD process reduces a dimension of the patterned feature, and the CVD process includes flowing a precursor gas into a chamber that infuses into the resist layer. In an embodiment, the method further comprises transferring the patterned feature into a layer below the resist layer.

### BACKGROUND

### 1) Field

Embodiments of the present disclosure pertain to the field of lithographic patterning improvement.

### 2) Description of Related Art

Lithography processes are used in semiconductor manufacturing in order to form various structures on and/or in a substrate. Limits of ultraviolet (UV) and deep ultraviolet (DUV) lithography have been exceeded as semiconductor devices continue to scale to smaller feature sizes (e.g., smaller critical dimensions (CDs)). Smaller CDs have been obtained through the use of extreme ultraviolet (EUV) lithography due to the smaller wavelength of the EUV radiation. However, the transition to EUV lithography is not without issue.

Particularly, significantly fewer photons reach the photoresist in EUV lithography solutions. This can lead to stochastic noise issues. For example, sidewall roughness is high. In order to mitigate the stochastic noise, image contrast can be increased. This can be done by providing larger openings in the mask and/or providing higher EUV dosages (e.g., longer exposure times). Larger openings limit the formation of small holes, and higher EUV dosages reduce throughput.

### SUMMARY

Embodiments disclosed herein include a method for treating a resist layer comprising a patterned feature with a chemical vapor deposition (CVD) process. In an embodiment, the CVD process reduces a dimension of the patterned feature, and the CVD process includes flowing a precursor gas into a chamber that infuses into the resist layer. In an embodiment, the method further comprises transferring the patterned feature into a layer below the resist layer.

Embodiments may further comprise a method that includes treating a resist layer with a patterned feature with a molecular layer deposition (MLD) process in a chamber. In an embodiment, the MLD process includes (a) supplying a pulse of a precursor gas into the chamber, and (b) purging the chamber.

Embodiments may further comprise a method that includes (a) treating a resist layer comprising a patterned feature with a first molecular layer deposition (MLD) process. In an embodiment, the first MLD process includes a first precursor gas with a formula of X₁—R₁—X₂, where R₁ is one or more of an alkyl group, an aromatic group, or a cycloalkyl group, where X₁ and X₂ are bonded to R₁ in any combination of the structural position, and where X₁ and X₂ comprise an amino group, a hydroxide group, an aldehyde group, or an acid group. In an embodiment, the method may further include (b) treating the resist layer with a second MLD process, wherein the second MLD process comprises a second precursor gas with a formula of Y₁—R₂—Y₂, wherein R₂ is one or more of an alkyl group, an aromatic group, or a cycloalkyl group, where Y₁ and Y₂ are bonded to R₂ in any combination of the structural position, and where Y₁ and Y₂ comprise an acyl chloride group, an isocyanate group, a thiocyanate group, an aldehyde group, an acid group, or a hydroxide group.

### BRIEF DESCRIPTION OF THE DRAWINGS

FIG. 1A is a plan view illustration of a substrate with a patterned resist layer with a bridged pair of holes, in accordance with an embodiment.

FIG. 1B is a plan view illustration of a substrate with a patterned resist layer with a missing hole, in accordance with an embodiment.

FIG. 1C is a cross-sectional illustration with a patterned resist layer with holes, in accordance with an embodiment.

FIG. 2A is a plan view illustration of a substrate with a patterned resist layer with a plurality of holes, in accordance with an embodiment.

FIG. 2B is a cross-sectional illustration of the substrate in FIG. 2A, in accordance with an embodiment.

FIG. 2C is a plan view illustration of the substrate after a molecular layer deposition (MLD) process is used to modify the resist layer, in accordance with an embodiment.

FIG. 2D is a cross-sectional illustration of the substrate in FIG. 2C, in accordance with an embodiment.

FIG. 2E is a plan view illustration of the substrate after the holes are transferred into an underlayer and the resist layer is removed, in accordance with an embodiment.

FIG. 2F is a cross-sectional illustration of the substrate in FIG. 2E, in accordance with an embodiment.

FIG. 3A is a plan view illustration of a substrate with a resist layer with holes patterned into the resist layer, in accordance with an embodiment.

FIG. 3B is a plan view illustration of the substrate after an MLD process is used to modify the resist layer, in accordance with an embodiment.

FIG. 3C is a plan view illustration of the substrate after the resist layer is treated with a post-treatment, in accordance with an embodiment.

FIG. 4A is a plan view illustration of a substrate with a resist layer with patterned holes, in accordance with an embodiment.

FIG. 4B is a plan view illustration of the substrate after a first MLD process is used to modify the resist layer, in accordance with an embodiment.

FIG. 4C is a plan view illustration of the substrate after a second MLD process is used to modify the resist layer, in accordance with an embodiment.

FIG. 4D is a plan view illustration of the substrate after the resist layer is treated with a post-treatment, in accordance with an embodiment.

FIG. 5A is a perspective view illustration of a substrate with a resist layer with patterned lines, in accordance with an embodiment.

FIG. 5B is a perspective view illustration of the substrate after an MLD process is used to modify the resist layer, in accordance with an embodiment.

FIG. 6 is a process flow diagram that illustrates a process for treating a resist layer with one or more MLD processes, in accordance with an embodiment.

FIG. 7 is a plan view illustration of a processing tool that may be used to treat a photoresist layer with one or more MLD processes, in accordance with an embodiment.

FIG. 8A is an illustration of various precursors that may be used for one or more MLD processes, in accordance with an embodiment.

FIG. 8B is an illustration of various precursors that may be used for one or more MLD processes, in accordance with an embodiment.

FIG. 9 illustrates a block diagram of an exemplary computer system of a processing tool, in accordance with an embodiment of the present disclosure.

### DETAILED DESCRIPTION

After develop resist treatment processes to reduce critical dimensions of patterned features are described, in accordance with various embodiments. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, extreme ultraviolet (EUV) lithography is strongly influenced by stochastic noise. Stochastic noise is reduced as image contrast increases. Illumination (or exposure) optimization is beneficial to maximize image contrast. For example, higher doses of EUV radiation can be used to improve local critical dimension uniformity (LCDU). This is due to the increase in photons that reach the resist, which brings the patterning to a more continuum state as opposed to a stochastically discrete state. However, the higher dose may result in decreases in throughput. This can make the EUV lithography more expensive and suboptimal for high volume manufacturing (HVM) environments.

In contact-hole cases, a large number of photons can be achieved by providing a higher dose and/or by providing a larger opening in the mask. Contact-hole mask critical dimension (CD) is a useful parameter which is related to the number of photons and dose, as well as image contrast. However, the drive to smaller feature sizes in the resist (e.g., smaller diameter holes) does not allow for large mask opening CDs. Currently, resolution limits for contact hole openings in EUV resist materials are limited to being down to approximately 40 nm.

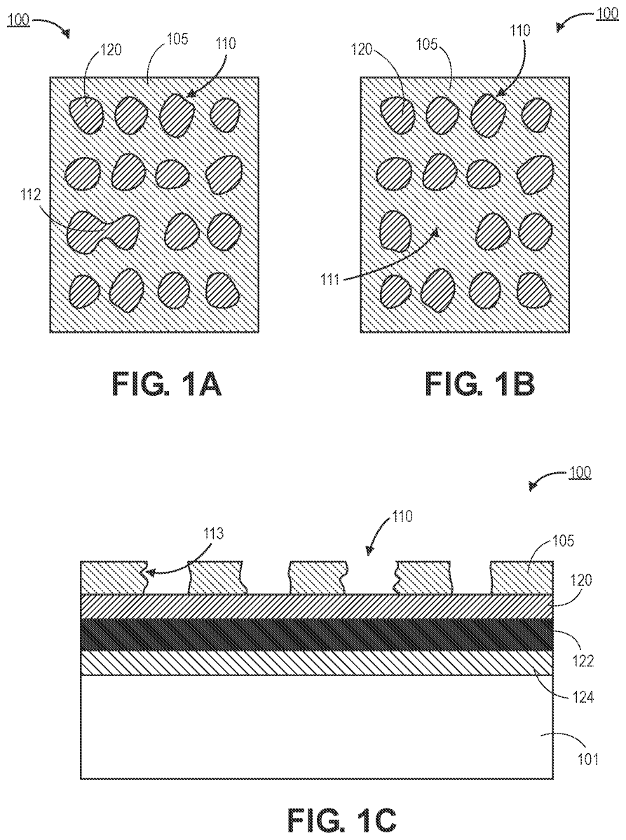

Referring now to FIG. 1A, a plan view illustration of a substrate 100 is shown, in accordance with an embodiment. The substrate 100 may comprise a resist layer 105 and an underlying layer 120. A plurality of holes 110 (e.g., contact holes) may be patterned into the resist layer 105 in order to expose portions of the underlying layer 120. In an embodiment, the holes 110 may be formed with an EUV exposure and developing process. As a result of stochastic behavior, the holes 110 may have slightly non-uniform diameters, non-perfect circular shapes, and/or other irregularities (e.g., CD non-uniformity). In a particular embodiment, a pair of adjacent holes may be linked together by a bridge 112 that is the result of an unintended overexposure. After pattern transfer and contact material deposition, the bridge 112 may result in the shorting of neighboring structures. This can lead to defective devices on the substrate 100.

FIG. 1B is an example of an opposite defect, where unintended underexposure is present. As shown in FIG. 1B, the resist layer 105 may have a missing hole in a region 111. A missing hole in the resist layer 105 can ultimately result in a missing contact. This defect can also result in a defective device on the substrate 100.

Referring now to FIG. 1C, a cross-sectional illustration of a substrate 100 similar to one of the substrates 100 in FIG. 1A and/or FIG. 1B is shown, in accordance with an embodiment. The substrate 100, may comprise a device layer 101. The device layer 101 may be a semiconductor material, such as silicon or the like. The device layer 101 may also be a dielectric material, such as a nitride, an oxide, and/or the like. In an embodiment, a carbon containing layer 124 (e.g., a spin on carbon (SOC)) may be provided over the device layer 101. A hardmask layer 122 may be provided over the carbon containing layer 124. The underlying layer 120 may be an underlayer.

As shown, the resist layer 105 comprises a plurality of holes 110. The holes 110 may have a relatively high sidewall 113 roughness. Additionally, diameters of the holes 110 may be non-uniform. The high roughness of the sidewalls 113 and the CD non-uniformity may be attributable to the stochastic nature of the EUV lithography process described in greater detail above. As the diameter of the holes 110 decreases, the magnitude of sidewall 113 roughness and CD non-uniformity increases.

Accordingly, embodiments disclosed herein include a treatment process that can be used in order to improve EUV lithography performance of the resist layer. Particularly, the resist layer may be exposed and developed with existing EUV lithography processes. Thereafter, a chemical vapor deposition (CVD) process may be implemented in order to modify the resist layer. In a particular embodiment, the CVD process is a molecular layer deposition (MLD) process. The CVD process (or the MLD process) may include flowing a precursor gas into a chamber, and the precursor gas interacts with the surface of the resist layer. For example, the precursor gas may infuse into the resist layer. This results in the swelling of the resist layer. As the resist layer swells, the diameter of the hole will decrease. Accordingly, scaling to smaller CDs can be obtained without needing to decrease mask opening size and without increasing EUV dosages. For example, diameters of the holes in the resist layer may be scaled to approximately 15 nm or smaller or approximately 10 nm or smaller. The swelling induced by the MLD process may also reduce sidewall roughness of the holes. It is to be appreciated that the CVD process and/or MLD processes disclosed herein are distinct from typical CVD processes where a distinct layer is provided over the surfaces of the resist layer. Instead, embodiments disclosed herein include infusing the precursor into the resist layer in order to achieve the desired swelling effect.

In an embodiment, the MLD process may use a single precursor gas. In another embodiment, the MLD process may include a first half-cycle with a first precursor gas and a second half-cycle with a second precursor that is different than the first precursor gas. The two half cycles may be repeated any number of times. In additional embodiments, post-treatment processes may be implemented after the MLD process in order to densify the resist layer. Increasing the density of the resist layer may improve etch resist in some embodiments. The post-treatment process may include a thermal treatment, an ion implantation treatment, a plasma treatment, or the like.

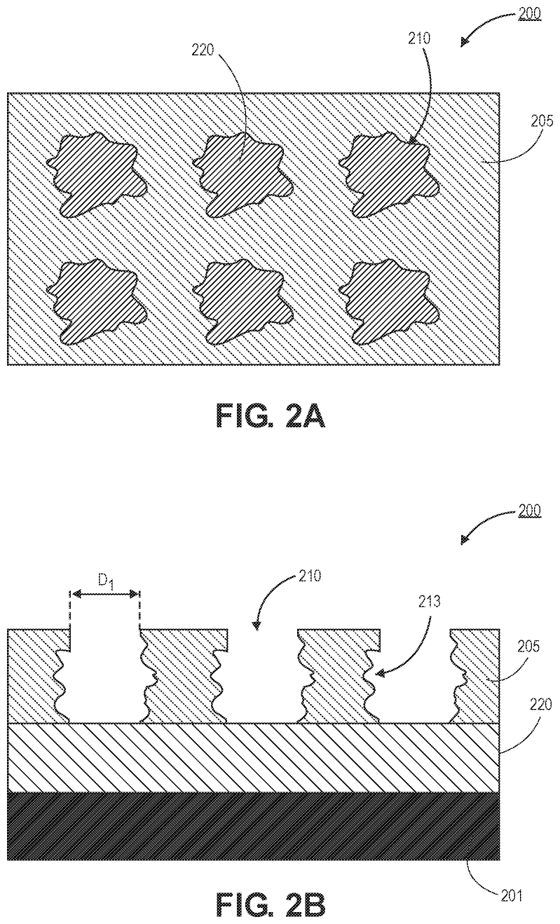

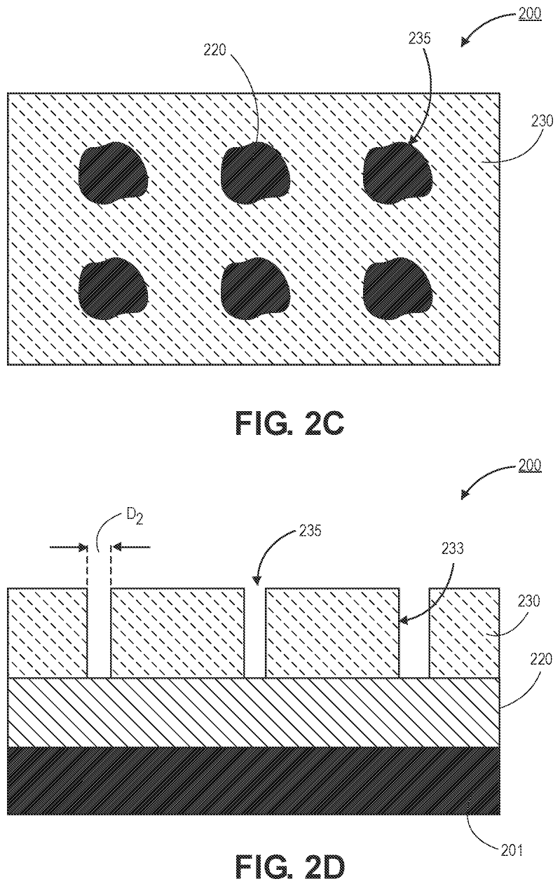

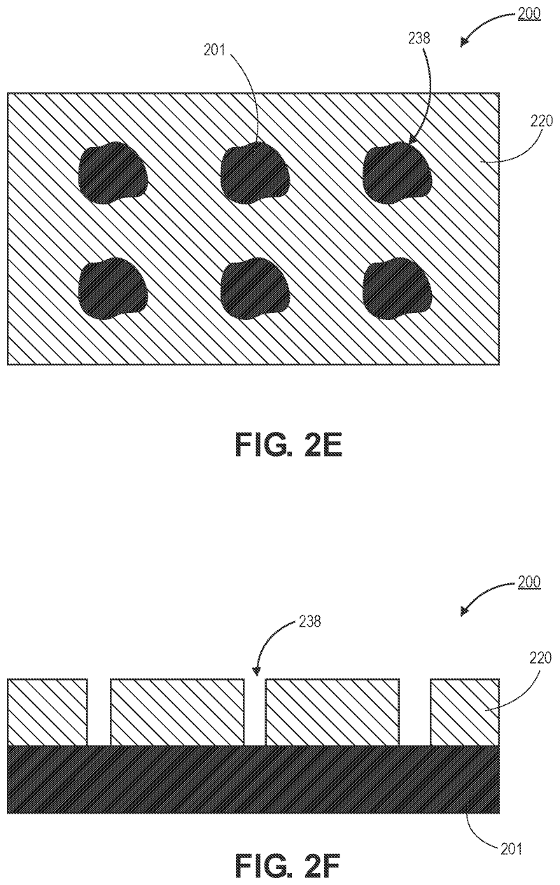

Referring now to FIGS. 2A-2F, a series of illustrations depicting a process for treating a resist layer 205 of a substrate 200 is shown, in accordance with an embodiment. In the embodiment shown in FIGS. 2A-2F, a half-cycle MLD process is implemented. A “half-cycle” may refer to the use of a single precursor gas for the MLD process.

Referring now to FIGS. 2A and 2B, a plan view illustration and a cross-sectional illustration of a substrate 200 with a resist layer 205 are shown, respectively, in accordance with an embodiment. In an embodiment, the substrate 200 may be similar to substrate 100 described in greater detail above. For example, the substrate 200 may comprise a device layer and one or more patterning layers in a patterning stack. A resist layer 205 may be provided as a topmost layer of the patterning stack. For example, the resist layer 205 is shown as being provided over an underlayer 220. A device layer 201 may be provided below the underlayer 220. Other layers of the substrate 200 between the underlayer 220 and the device layer 201 (e.g., hardmask layers, etc.) are omitted for simplicity.

In an embodiment, the resist layer 205 may be any suitable type of resist. In a particular embodiment, the resist layer 205 is a chemically amplified resist (CAR). Though, metal oxide based resists may also be used in some embodiments. While MLD processes described herein are particularly beneficial for positive tone CAR resists, it is to be appreciated that negative tone resists may also be used in conjunction with MLD processes described herein. In an embodiment, the resist layer 205 is tuned to initiate chemical reactions in order to provide a solubility switch in the resist layer 205 when exposed to EUV radiation. EUV radiation may refer to electromagnetic radiation with a wavelength from 10 nm to 120 nm. While particularly beneficial for EUV lithography operations, embodiments disclosed herein may also include MLD process to improve lithography based on wavelengths outside of the EUV band.

In an embodiment, the resist layer 205 has been exposed and developed to form one or more patterned features into the resist layer 205. For example, the patterned features in FIGS. 2A and 2B may be holes 210. Due to the stochastic nature of EUV lithography, the holes 210 may have sidewalls 213 with relatively high roughness. Additionally, limitations on CD scaling may limit the scaling to small dimension holes 210. For example, the holes 210 may have a first diameter D₁. The first diameter D₁ may refer to a diameter (or width) of the hole 210 across an opening at a top of the resist layer 205. Due to variations in the EUV lithography process, the holes 210 may not all have the same first diameter D₁. That is, the first diameter D₁ may refer to a single hole 210, or the first diameter D₁ may refer to an average diameter of two or more holes 210 within the resist layer 205. In an embodiment, the first diameter D₁ may be as small as approximately 40 nm, as small as approximately 30 nm, or as small as approximately 20 nm.

Referring now to FIGS. 2C and 2D, a plan view illustration and a cross-sectional illustration of the substrate 200 after an MLD process is applied to the resist layer 205 are shown, respectively, in accordance with an embodiment. The MLD process may result in a modification of the resist layer 205 in order to form a modified resist layer 230. The modified resist layer 230 may undergo a “swelling” or “expansion” compared to the resist layer 205. That is, the modified resist layer 230 may have a larger volume than the original resist layer 205. In an embodiment, the swelling is the result of the MLD process since the applied precursor gas infuses into the resist layer 205. In some embodiments, material characterization of the modified resist layer 230 may be used to identify the presence of the precursor gas molecules proximate to surfaces of the modified resist layer 230. For example, Fourier transform infrared (FTIR) spectroscopy may be used to identify chemical compounds of the precursor within the modified resist layer 230.

The swelling process results in the reduction of a dimension of the holes 210. For example, holes 235 within the modified resist layer 230 may have a second diameter D₂ that is smaller than the first diameter D₁ of the holes 210. The reduction in diameter may provide a second diameter D₂ that is smaller than the first diameter D₁ by up to approximately 10 nm, up to approximately 5 nm, or up to approximately 1 nm. In other embodiments, the second diameter D₂ may be up to 10% smaller than the first diameter D₁, up to 5% smaller than the first diameter D₁, or up to 3% smaller than the first diameter D₁. In an embodiment, the swelling process may also smooth out the sidewalls 233 of the modified resist layer 230. That is, the roughness of sidewalls 233 may be smaller than the roughness of sidewalls 213.

As can be appreciated, the reduction in the second diameter D₂ of holes 235 allows for enhanced scaling to smaller CDs compared to existing solutions. Generally, a relatively large hole 210 can be formed in the resist layer 205. This allows for lower dosages, and does not put a high demand on shrinking openings in the mask used for the lithography exposure process. Thereafter, the CD is shrunk through the MLD process to provide the improved scaling. Stated differently, further scaling to smaller CDs is not dependent on exposure characteristics (e.g., the typically stochastic state of EUV lithography). This allows for improved scaling without sacrificing throughput or LCDU.

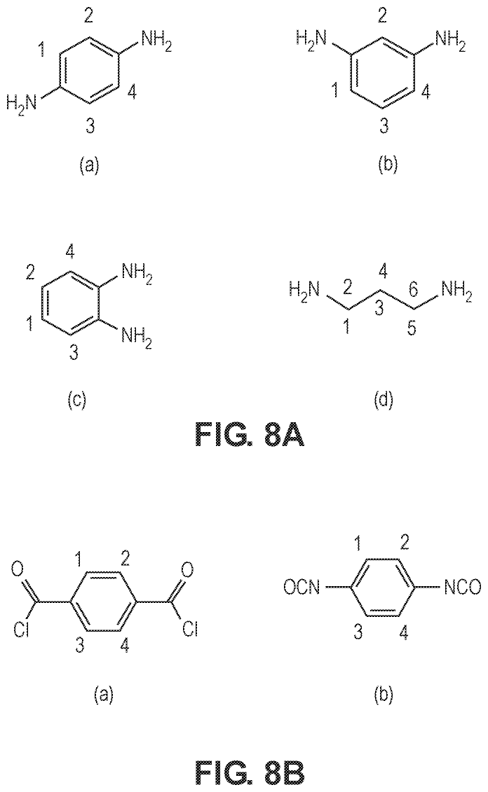

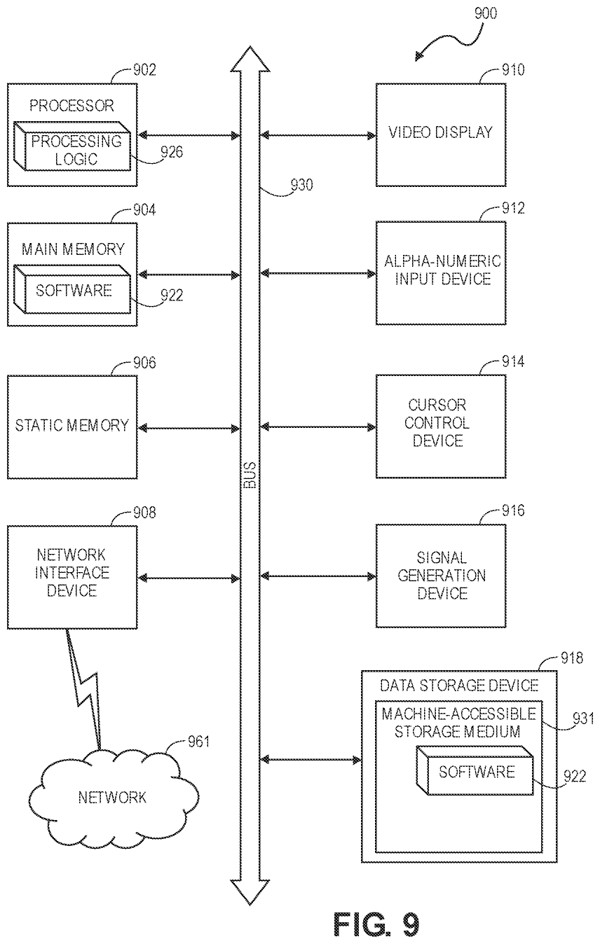

In an embodiment, the MLD process may comprise supplying a pulse of a precursor gas into a chamber housing the substrate 200. In an embodiment, the precursor gas may be any suitable precursor gas compatible with uptake by the resist layer 205. For example, the precursor gas may comprise one or more of ethylenediamine or terephthaloyl chloride. Though, it is to be appreciated that many different precursors are available for use in the MLD process in accordance with embodiments disclosed herein. More generally, the precursors may have the general formula of X₁—R₁—X₂, where R₁ can be one or more of an alkyl group, an aromatic group, or a cycloalkyl group (with or without sidechains or the like). X₁ and X₂ may be bonded to R₁ in any combination of the structural position, and can chemically be an amino group, a hydroxide group, an aldehyde group, an acid group, or the like. For example, FIG. 8A lists a sequence of precursors (a)-(d) that conform to the generic X₁—R₁—X₂ formula. In each precursor (a)-(d), one or more of the labeled carbons (1-6) of the phenyl ring may be bonded to an additional chemical structure X, where X may be H, F, Br, Cl, NO₂, CH₃, or the like. Additionally, the diamine structures may comprise different carbon chain lengths, and/or side chains. Further, the —NH₂ groups of the precursors (a)-(d) may be replaced with one or more of a hydroxide group, an aldehyde group, a ketone group, an acid group, an isocyanate group, a thiocyanate group, or the like. After applying the pulse of the precursor gas, a purging operation may be implemented to clear the chamber. The MLD process may comprises cycling the precursor pulsing and purging operations a plurality of times (e.g., 5 or more times, 10 or more times, 50 or more times, or 100 or more time).

In an embodiment, the processing conditions within the chamber may be varied in order to provide a desired reduction in the dimension of the patterned feature (e.g., the diameter of the holes 235). For example, a temperature within the chamber during the MLD process may be between 20° C. and 150° C. Though, lower or higher temperatures may also be used in some embodiments. In an embodiment, a pressure within the chamber during portions of the MLD process may be up to approximately 1 Torr or up to approximately 5 Torr. Though higher pressures may also be used in other embodiments. Embodiments may include different pulse durations. For example, the pulse duration may be up to approximately 1 second, up to approximately 10 seconds, up to approximately 30 seconds, or up to approximately 1 minute. Though, longer pulse durations may also be used in some embodiments.

Referring now to FIGS. 2E and 2F, a plan view illustration and a cross-sectional illustration of the substrate 200 after the patterned features are transferred into the underlayer 220 are shown, respectively, in accordance with an embodiment. In an embodiment, the underlayer 220 may be patterned with an etching process that uses the modified resist layer 230 as a mask. The etching process may be a dry etching process or a wet etching process. For example, holes 238 may be formed into the underlayer 220 with the etching process. As shown in FIG. 2E, the holes 238 expose portions of the underlying device layer 201. Due to the masking process, the holes 238 may have substantially the same diameter as the holes 235 in the modified resist layer 230.

After the pattern transfer into the underlayer 220, the modified resist layer 230 may be removed with any suitable process (e.g., a resist stripping process). The pattern transfer into the underlayer 220 may also be applied to any other layers (not shown) in the patterning stack (e.g., carbon layers, hardmask layers, etc.). Once the patterning stack is patterned, the pattern may be transferred into the device layer 201.

In some embodiments, the underlayer 220 may also be treated with an MLD process similar to any of those described in greater detail herein. The underlayer 220 may be treated with the MLD process in addition to using an MLD process to treat the resist layer 205. In other embodiments, the resist layer 205 may be untreated, and the underlayer 220 is treated with the MLD process in order to reduce a dimension of the pattern formed in the underlayer 220 using typical pattern transfer processes.

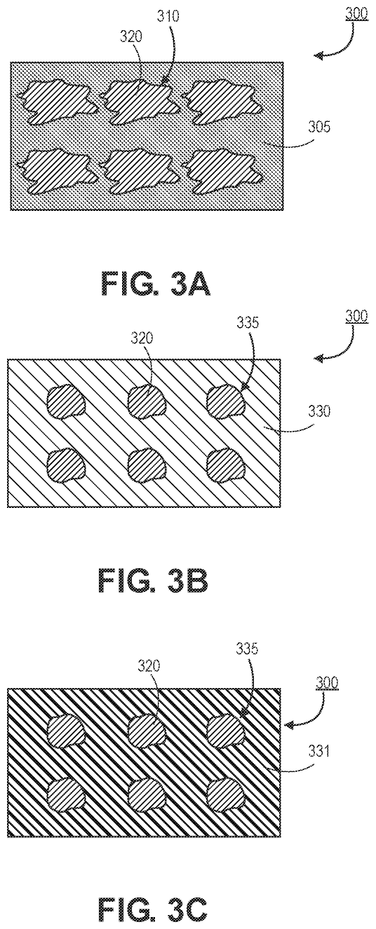

Referring now to FIGS. 3A-3C, a series of plan view illustrations depicting a process for treating a resist layer 305 of a substrate 300 is shown, in accordance with an embodiment. In the embodiment shown in FIGS. 3A-3C, a half-cycle MLD process is implemented. The half-cycle may further include a post-treatment process in order to further modify the resist layer 305 to improve pattern transfer.

Referring now to FIG. 3A, a plan view illustration of a substrate 300 with a resist layer 305 is shown, in accordance with an embodiment. In an embodiment, the substrate 300 may be similar to substrate 100 described in greater detail above. For example, the substrate 300 may comprise a device layer and one or more patterning layers in a patterning stack. A resist layer 305 may be provided as a topmost layer of the patterning stack. For example, the resist layer 305 is shown as being provided over an underlayer 320. A device layer may be provided below the underlayer 320. Other layers between the underlayer 320 and the device layer (e.g., hardmask layers, etc.) may also be provided on the substrate 300.

In an embodiment, the resist layer 305 may be similar to resist layer 205 described in greater detail above. For example, the resist layer 305 may be a CAR, a metal oxide based resist, or the like. The resist layer 305 may be a positive tone resist or a negative tone resist. The resist layer 305 may be an EUV compatible resist. Though, embodiments disclosed herein may also include resists compatible with electromagnetic radiation outside of the EUV band.

In an embodiment, the resist layer 305 has been exposed and developed to form one or more patterned features into the resist layer 305. For example, the patterned features in FIG. 3A may be holes 310. Limitations on CD scaling may limit the scaling of the diameter of the holes 310. For example, the holes 310 may have a first diameter. The first diameter may refer to a diameter (or width) of the hole 310 across an opening at a top of the resist layer 305. In an embodiment, the first diameter may be as small as approximately 40 nm, as small as approximately 30 nm, or as small as approximately 20 nm.

Referring now to FIGS. 3B, a plan view illustration of the substrate 300 after an MLD process is applied to the resist layer 305 is shown, in accordance with an embodiment. The MLD process may result in a modification of the resist layer 305 in order to form a modified resist layer 330. The modified resist layer 330 may undergo a “swelling” or “expansion” compared to the resist layer 305. That is, the modified resist layer 330 may have a larger volume than the original resist layer 305. In an embodiment, the swelling is the result of the MLD process since the applied precursor gas infuses into the resist layer 305.

The swelling process results in the reduction of a dimension of the holes 310. For example, holes 335 within the modified resist layer 330 may have a second diameter that is smaller than the first diameter of the holes 310. The reduction in diameter may provide a second diameter that is smaller than the first diameter by up to approximately 10 nm, up to approximately 5 nm, or up to approximately 1 nm. In other embodiments, the second diameter may be up to 10% smaller than the first diameter, up to 5% smaller than the first diameter, or up to 3% smaller than the first diameter. In an embodiment, the swelling process may also smooth out the sidewalls of the modified resist layer 330. That is, the roughness of sidewalls may be smaller than the roughness of sidewalls.

As can be appreciated, the reduction in the second diameter of holes 335 allows for enhanced scaling to smaller CDs compared to existing solutions. Generally, a relatively large hole 310 can be formed in the resist layer 305. This allows for lower dosages, and does not put a high demand on shrinking openings in the mask used for the lithography exposure process. Thereafter, the CD is shrunk through the MLD process to provide the improved scaling. Stated differently, further scaling to smaller CDs is not dependent on exposure characteristics (e.g., the typically stochastic state of EUV lithography). This allows for improved scaling without sacrificing throughput or LCDU.

In an embodiment, the MLD process may be substantially similar to the MLD process described above with respect to FIGS. 2C and 2D. For example, the MLD process may comprise supplying a pulse of a precursor gas into a chamber housing the substrate 300. In an embodiment, the precursor gas may be any suitable precursor gas compatible with uptake by the resist layer 305. For example, the precursor gas may comprise one or more of ethylenediamine or terephthaloyl chloride. Though, it is to be appreciated that many different precursors are available for use in the MLD process in accordance with embodiments disclosed herein. More generally, the precursors may have the general formula of X₁—R₁—X₂, where R₁ can be one or more of an alkyl group, an aromatic group, or a cycloalkyl group (with or without sidechains or the like). X₁ and X₂ may be bonded to R₁ in any combination of the structural position, and can chemically be an amino group, a hydroxide group, an aldehyde group, an acid group, or the like. For example, FIG. 8A lists a sequence of precursors (a)-(d) that may be used. In each precursor (a)-(d), one or more of the labeled carbons (1-6) of the phenyl ring may be bonded to an additional chemical structure X, where X may be H, F, Br, Cl, NO₂, CH₃, or the like. Additionally, the diamine structures may comprise different carbon chain lengths, and/or side chains. Further, the —NH₂ groups of the precursors (a)-(d) may be replaced with one or more of a hydroxide group, an aldehyde group, a ketone group, an acid group, an isocyanate group, a thiocyanate group, or the like. After applying the pulse of the precursor gas, a purging operation may be implemented to clear the chamber. The MLD process may comprises cycling the precursor pulsing and purging operations a plurality of times (e.g., 5 or more times, 10 or more times, 50 or more times, or 100 or more time). Processing conditions for the MLD process in FIG. 3B may be similar to any of the MLD processes described in greater detail herein.

Referring now to FIG. 3C, a plan view illustration of the substrate 300 after a post-treatment process is applied to the modified resist layer 330 is shown, in accordance with an embodiment. The post-treatment process may result in the conversion of the modified resist layer 330 into a treated resist layer 331. In an embodiment, the post-treatment process may be used in order to improve pattern transfer properties of the treated resist layer 331 compared to the modified resist layer 330. For example, the post-treatment process may include a thermal treatment. The thermal treatment may be used to densify the treated resist layer 331, which may improve an etch resistance of the treated resist layer 331. Thermal treatments may include heating the substrate 300 with a heated stage, a heated chuck, through a laser flash anneal, and/or the like. The substrate 300 may be heated from approximately 40° C. and approximately 300° C. Though, lower or higher temperatures may also be used for a thermal treatment. In an embodiment, the post-treatment may also include treatments, such as an ion implantation treatment, a plasma treatment, and/or the like.

In an embodiment, the post-treatment process shown in FIG. 3C may be implemented after the MLD process is fully completed. In other embodiments, post-treatment processes may be implemented after one or more half-cycles of the MLD process. That is, a “post-treatment” operation may not be after all MLD processing in some embodiments.

After the substrate 300 undergoes a post-treatment to form a treated resist layer 331, the patterned holes 335 may be transferred into the underlayer 320. For example, the pattern transfer process may be similar to the pattern transfer process described above with respect to FIGS. 2E and 2F.

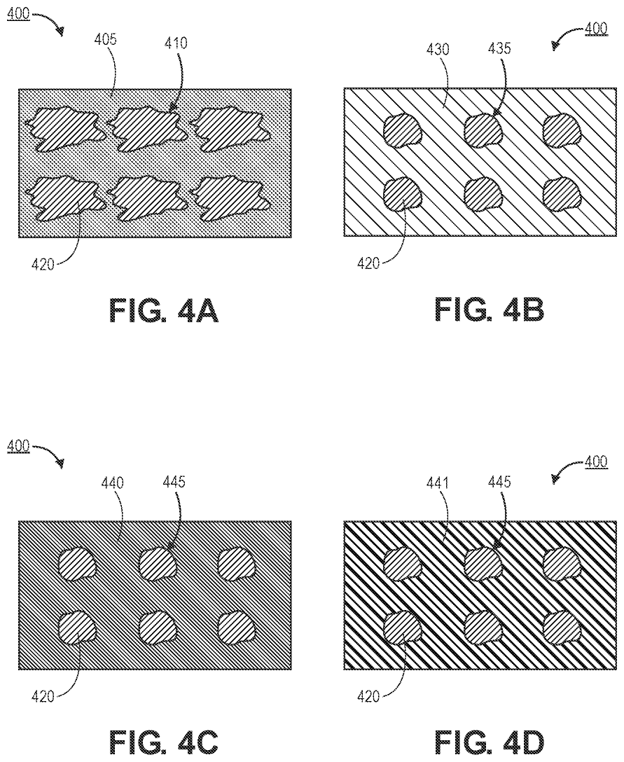

Referring now to FIGS. 4A-4D, a series of plan view illustrations depicting a process for treating a resist layer 405 of a substrate 400 is shown, in accordance with an embodiment. In the embodiment shown in FIGS. 4A-4D, a full-cycle MLD process is implemented. A full-cycle MLD process may refer to a process that includes a first MLD process with a first precursor gas and a second MLD process with a second precursor gas. The full-cycle may further include a post-treatment process in order to further modify the resist layer 405 to improve pattern transfer.

Referring now to FIG. 4A, a plan view illustration of a substrate 400 with a resist layer 405 is shown, in accordance with an embodiment. In an embodiment, the substrate 400 may be similar to substrate 100 described in greater detail above. For example, the substrate 400 may comprise a device layer and one or more patterning layers in a patterning stack. A resist layer 405 may be provided as a topmost layer of the patterning stack. For example, the resist layer 405 is shown as being provided over an underlayer 420. A device layer may be provided below the underlayer 420. Other layers between the underlayer 420 and the device layer (e.g., hardmask layers, etc.) may also be provided on the substrate 400.

In an embodiment, the resist layer 405 may be similar to resist layer 205 described in greater detail above. For example, the resist layer 405 may be a CAR, a metal oxide based resist, or the like. The resist layer 405 may be a positive tone resist or a negative tone resist. The resist layer 405 may be an EUV compatible resist. Though, embodiments disclosed herein may also include resists compatible with electromagnetic radiation outside of the EUV band. In an embodiment, the resist layer 405 has been exposed and developed to form one or more patterned features into the resist layer 405. For example, the patterned features in FIG. 4A may be holes 410.

Referring now to FIGS. 4B, a plan view illustration of the substrate 400 after a first MLD process is applied to the resist layer 405 is shown, in accordance with an embodiment. The first MLD process may result in a modification of the resist layer 405 in order to form a modified resist layer 430. The modified resist layer 430 may undergo a “swelling” or “expansion” compared to the resist layer 405. That is, the modified resist layer 430 may have a larger volume than the original resist layer 405.

The swelling process results in the reduction of a dimension of the holes 410. For example, holes 435 within the modified resist layer 430 may have a diameter that is smaller than a diameter of the holes 410. The reduction in diameter may provide a second diameter that is smaller than the first diameter by up to approximately 10 nm, up to approximately 5 nm, or up to approximately 1 nm. In other embodiments, the second diameter may be up to 10% smaller than the first diameter, up to 5% smaller than the first diameter, or up to 3% smaller than the first diameter. In an embodiment, the swelling process may also smooth out the sidewalls of the modified resist layer 430. That is, the roughness of sidewalls may be smaller than the roughness of sidewalls.

In an embodiment, the first MLD process may be substantially similar to any of the MLD processes described herein. For example, the first MLD process may comprise supplying a pulse of a first precursor gas into a chamber housing the substrate 400. In an embodiment, the first precursor gas may be any suitable precursor gas compatible with uptake by the resist layer 405. For example, the first precursor gas may comprise one or more of ethylenediamine or terephthaloyl chloride. Though, it is to be appreciated that many different precursors are available for use in the MLD process in accordance with embodiments disclosed herein. More generally, the precursors may have the general formula of X₁—R₁—X₂, where R₁ can be one or more of an alkyl group, an aromatic group, or a cycloalkyl group (with or without sidechains or the like). X₁ and X₂ may be bonded to R₁ in any combination of the structural position, and can chemically be an amino group, a hydroxide group, an aldehyde group, an acid group, or the like. For example, FIG. 8A lists a sequence of precursors (a)-(d) that may be used. In each precursor (a)-(d), one or more of the labeled carbons (1-6) of the phenyl ring may be bonded to an additional chemical structure X, where X may be H, F, Br, CI, NO₂, CH₃, or the like. Additionally, the diamine structures may comprise different carbon chain lengths, and/or side chains. Further, the —NH₂ groups of the precursors (a)-(d) may be replaced with one or more of a hydroxide group, an aldehyde group, a ketone group, an acid group, an isocyanate group, a thiocyanate group, or the like. After applying the pulse of the precursor gas, a purging operation may be implemented to clear the chamber. The first MLD process may comprises cycling the precursor pulsing and purging operations a plurality of times (e.g., 5 or more times, 10 or more times, 50 or more times, or 100 or more time). Processing conditions for the MLD process in FIG. 4B may be similar to any of the MLD processes described in greater detail herein.

Referring now to FIG. 4C, a plan view illustration of the substrate 400 after a second MLD process is shown, in accordance with an embodiment. The second MLD process may result in a further change in the modified resist layer 440 (as indicated by the different shading). The holes 445 through the resist layer 440 may be similar in dimension and surface roughness as the holes 435. Though, in some embodiments the second MLD process may provide additional swelling that further shrinks a diameter of the holes 445 relative to a diameter of the holes 435.

In an embodiment, the second MLD process may be substantially similar to any of the MLD processes described herein. For example, the second MLD process may comprise supplying a pulse of a second precursor gas into a chamber housing the substrate 400. In an embodiment, the second precursor gas may be any suitable precursor gas compatible with uptake by the resist layer 405. For example, the second precursor gas may comprise one or more of ethylenediamine or terephthaloyl chloride. In a particular embodiment, the second precursor gas is different than the first precursor gas. For example, the first precursor gas may comprise ethylenediamine and the second precursor gas may comprise terephthaloyl chloride. Though, it is to be appreciated that many different precursors are available for use in the MLD process in accordance with embodiments disclosed herein. More generally, the precursors may have the general formula of Y₁—R₂—Y₂, where R₂ can be one or more of an alkyl group, an aromatic group, or a cycloalkyl group (with or without sidechains or the like). Y₁ and Y₂ may be bonded to R₂ in any combination of the structural position, and can chemically be an acyl chloride group, an isocyanate group, a thiocyanate group, an aldehyde group, an acid group, a hydroxide group, or the like. FIG. 8B may also include precursors (a) and (b) that may be used in some embodiments. In each precursor (a)-(b), one or more of the labeled carbons (1-4) of the phenyl ring may be bonded to an additional chemical structure X, where X may be H, F, Br, Cl, NO₂, CH₃, or the like. Additionally, chlorine species of precursor (a) and/or precursor (b) may be replaced with hydrogen or the like. Furthermore, the phenyl groups may be replaced with a cycloalkane or with different carbon chain lengths and/or side chains. After applying the pulse of the second precursor gas, a purging operation may be implemented to clear the chamber. The second MLD process may comprises cycling the precursor pulsing and purging operations a plurality of times (e.g., 5 or more times, 10 or more times, 50 or more times, or 100 or more time). Processing conditions for the MLD process in FIG. 4C may be similar to any of the MLD processes described in greater detail herein.

In an embodiment, the two half-cycles (i.e., the first MLD process and the second MLD process) may be cycled any number of times. For example, the first MLD process and the second MLD process may be cycled 2 or more times, 5 or more times, 10 or more times, 20 or more times, or 100 or more times.

Referring now to FIG. 4D, a plan view illustration of the substrate 400 after a post-treatment process is applied to the modified resist layer 440 is shown, in accordance with an embodiment. The post-treatment process may result in the conversion of the modified resist layer 440 into a treated resist layer 441. In an embodiment, the post-treatment process may be used in order to improve pattern transfer properties of the treated resist layer 441 compared to the modified resist layer 440 or 430. For example, the post-treatment process may include a thermal treatment. The thermal treatment may be used to densify the treated resist layer 441, which may improve an etch resistance of the treated resist layer 441. Thermal treatments may include heating the substrate 400 with a heated stage, a heated chuck, through a laser flash anneal, and/or the like. The substrate 400 may be heated from approximately 40° C. and approximately 300° C. Though, lower or higher temperatures may also be used for a thermal treatment. In an embodiment, the post-treatment may also include treatments, such as an ion implantation treatment, a plasma treatment, and/or the like.

In an embodiment, the post-treatment process shown in FIG. 4D may be implemented after the second MLD process is fully completed. In other embodiments, post-treatment processes may be implemented after one or more half-cycles of the second MLD process. That is, a “post-treatment” operation may not be after all the second MLD processing in some embodiments. In other embodiments, a similar post-treatment process may be implemented between the first MLD process and the second MLD process. Embodiments may also include a post-treatment process during the first MLD process, similar to other embodiments described herein.

After the substrate 400 undergoes a post-treatment to form a treated resist layer 441, the patterned holes 445 may be transferred into the underlayer 420. For example, the pattern transfer process may be similar to the pattern transfer process described above with respect to FIGS. 2E and 2F.

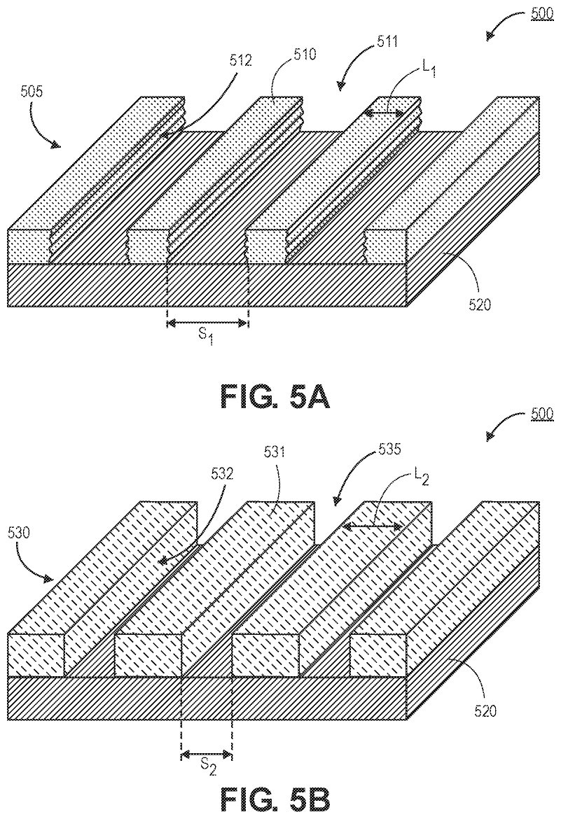

Referring now to FIGS. 5A and 5B, a pair of perspective view illustrations of a substrate 500 with a resist layer 505 that includes a different type of patterned feature is shown, in accordance with an embodiment. Instead of holes, the resist layer 505 may comprise lines 510 and spaces 511 (or trenches). The lines 510 may include a first line width L₁ and the spaces 511 may have a first spacing S₁. Sidewalls 512 of the lines 510 may have a rough surface.

In an embodiment, the resist layer 505 may be similar to any of the resist layers described in greater detail herein. For example, the resist layer 505 may be an EUV compatible CAR in some embodiments. In an embodiment, the resist layer 505 is provided over an underlayer 520. Additional layers (not shown) may be provided below the underlayer 520 similar to other embodiments described in greater detail herein. For example, substrate 500 may comprise a device layer, a hardmask layer, and/or the like.

Referring now to FIG. 5B, a perspective view illustration of the substrate 500 after an MLD process is shown, in accordance with an embodiment. As shown, the MLD process may result in the swelling of the resist layer 505 to form a modified resist layer 530 with swollen lines 531. The swollen lines 531 may have a second line width L₂ that is greater than the first line width L₁. As such, the second spacing S₂ of the spaces 535 between swollen lines 531 is reduced compared to the first spacing S₁. The swollen lines 531 may also have sidewalls 532 with a lower roughness than sidewalls 512. Therefore, CD scaling is enabled for line/space patterning as well.

In an embodiment, the MLD process used in FIG. 5B may be similar to any of the MLD processes described in greater detail herein. For example, the MLD process may be a half-cycle MLD process or a full-cycle MLD process. The MLD process may also comprise one or more post-treatments. It is to be appreciated that many different precursors are available for use in the MLD process in accordance with embodiments disclosed herein. Generally, the precursors for a first half-cycle may have the general formula of X₁—R₁—X₂, where R₁ can be one or more of an alkyl group, an aromatic group, or a cycloalkyl group (with or without sidechains or the like). X₁ and X₂ may be bonded to R₁ in any combination of the structural position, and can chemically be an amino group, a hydroxide group, an aldehyde group, an acid group, or the like. For example, FIG. 8A lists a sequence of precursors (a)-(d) that may be used. In each precursor (a)-(d), one or more of the labeled carbons (1-6) of the phenyl ring may be bonded to an additional chemical structure X, where X may be H, F, Br, Cl, NO₂, CH₃, or the like. Additionally, the diamine structures may comprise different carbon chain lengths, and/or side chains. Further, the —NH₂ groups of the precursors (a)-(d) may be replaced with one or more of a hydroxide group, an aldehyde group, a ketone group, an acid group, an isocyanate group, a thiocyanate group, or the like. Additionally, the precursors may have the general formula of Y₁—R₂—Y₂, where R₂ can be one or more of an alkyl group, an aromatic group, or a cycloalkyl group (with or without sidechains or the like). Y₁ and Y₂ may be bonded to R₂ in any combination of the structural position, and can chemically be an acyl chloride group, an isocyanate group, a thiocyanate group, an aldehyde group, an acid group, a hydroxide group, or the like. FIG. 8B may also include precursors (a) and (b) that may be used in some embodiments. In each precursor (a)-(b), one or more of the labeled carbons (1-4) of the phenyl ring may be bonded to an additional chemical structure X, where X may be H, F, Br, Cl, NO₂, CH₃, or the like. Additionally, chlorine species of precursor (a) and/or precursor (b) may be replaced with hydrogen or the like. Furthermore, the phenyl groups may be replaced with a cycloalkane or with different carbon chain lengths and/or side chains.

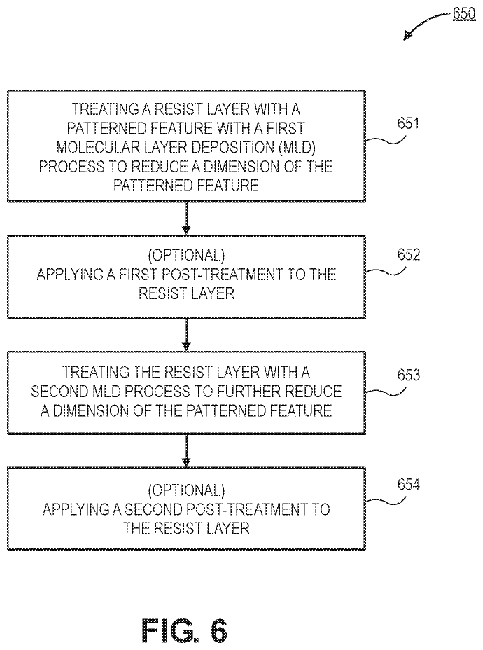

Referring now to FIG. 6, a process flow diagram of a process 650 for treating a resist layer with an MLD process is shown, in accordance with an embodiment. In an embodiment, the process 650 may include an MLD process similar to any of those described in greater detail herein.

In an embodiment, the process 650 may begin with operation 651, which comprises treating a resist layer with a patterned feature with a first MLD process. In an embodiment, the first MLD process may result in a reduction of a dimension of the patterned feature. For example, in the case where the patterned feature is a hole, a diameter of the hole may be reduced. In the case where the patterned feature is a line, a spacing between lines may be reduced. The first MLD process may use any suitable precursor gas and any suitable processing conditions, such as any of those described in greater detail herein.

In an embodiment, the process 650 may continue with operation 652, which comprises applying a first post-treatment to the resist layer. The first post-treatment may include a thermal treatment, an ion implantation treatment, and/or a plasma treatment. The first post-treatment may be used to improve the patterning performance of the resist layer. For example, the first post-treatment may densify the resist layer.

In an embodiment, the process 650 may continue with operation 653, which comprises treating the resist layer with a second MLD process. In an embodiment, the second MLD process may further reduce the dimension of the patterned feature in some embodiments. In an embodiment, the second MLD process may be different than the first MLD process. For example, the first MLD process and the second MLD process may comprise different precursor gasses.

In an embodiment, the process 650 may continue with operation 654, which comprises applying a second post-treatment to the resist layer. The second post-treatment may include a thermal treatment, an ion implantation treatment, and/or a plasma treatment. The second post-treatment may be used to improve the patterning performance of the resist layer. For example, the second post-treatment may densify the resist layer. In an embodiment, the second post-treatment may be different than the first post-treatment. In other embodiments, the second post-treatment and the first post-treatment may be similar or the same.

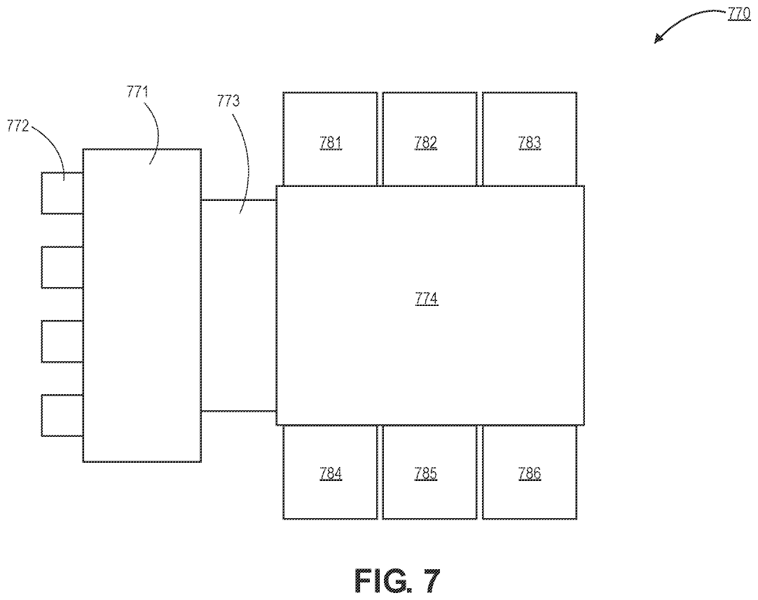

Referring now to FIG. 7, a plan view illustration of a semiconductor processing tool 770 is shown, in accordance with an embodiment. In an embodiment, the semiconductor processing tool 770 may be a cluster tool that is suitable for implementing lithography pattern transfer operations that include one or more MLD processes, such as those described in greater detail herein.

In an embodiment, the cluster tool may comprise an equipment front end module (EFEM) 771. The EFEM 771 may receive front opening unified pods (FOUPs) 772 or other wafer transport devices. A wafer handling robot within the EFEM 771 transfers wafers from the FOUP 772 to a load lock 773. The load lock 773 is coupled to a transfer chamber 774 that is held at a vacuum pressure. That is, the load lock 773 allows for the transition from an atmospheric pressure environment to a vacuum environment. A wafer handling robot within the transfer chamber 774 can distribute wafers from the load lock 773 to any of the chambers or stations 781-786 that are coupled to the transfer chamber 774.

In an embodiment, the chambers or stations 781-786 may be used in order to implement one or more processing operations of the lithography pattern transfer process. In one embodiment, chamber 781 may be a pre-treatment chamber. The pre-treatment chamber 781 may include annealing equipment, plasma generation equipment, and/or the like. The pre-treatment chamber 781 may be used to prepare surfaces of the resist layer for MLD processes.

In an embodiment, the chamber 782 may be a chamber for implementing one or more MLD processes. For example, chamber 782 may be a vacuum chamber that is capable of flowing one or more precursors into the chamber in order to modify the resist layer. The MLD processes implemented in chamber 782 may be similar to any of the MLD processes described in greater detail herein.

In an embodiment, the chamber 783 may be a post-treatment chamber 783. The post-treatment chamber may be suitable for providing thermal treatments, ion implantation treatments, plasma treatments, or the like. For example, the post-treatment chamber 783 may be used to densify the resist layer before pattern transfer. The post-treatments implemented in the post-treatment chamber 783 may be similar to any of the post-treatments described in greater detail herein.

In an embodiment, the chamber 784 may be an integrated on-board metrology tool. For example, the chamber 784 may be suitable for providing ellipsometry, IR measurements, and/or the like. The metrology chamber 784 may be used to monitor properties of the resist layer before and/or after treatment processes.

In an embodiment, the chamber 785 may be an etch chamber 785. The etch chamber 785 may be used to transfer the patterned feature within the resist layer into an underlying layer (or layers). The etch chamber 785 may be a dry etching chamber or a wet etching chamber.

In an embodiment, the chamber 786 may be a resist stripping chamber 786. The resist stripping chamber 786 may be used after the pattern has been transferred into one or more layers below the resist layer. After the pattern transfer, the resist layer may be stripped.

Referring now to FIG. 8, a block diagram of an exemplary computer system 800 of a processing tool is illustrated in accordance with an embodiment. In an embodiment, computer system 800 is coupled to and controls processing in the processing tool. The computer system 800 may be communicatively coupled to one or more vapor concentration sensor modules, such as those disclosed herein. The computer system 800 may utilize outputs from the one or more vapor concentration sensor modules in order to modify one or more parameters, such as, for example, processing recipe parameters, cleaning schedules for the processing tool, component replacement determinations, and the like.

Computer system 800 may be connected (e.g., networked) to other machines in a Local Area Network (LAN), an intranet, an extranet, or the Internet. Computer system 800 may operate in the capacity of a server or a client machine in a client-server network environment, or as a peer machine in a peer-to-peer (or distributed) network environment. Computer system 800 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 800, the term “machine” shall also be taken to include any collection of machines (e.g., computers) that individually or jointly execute a set (or multiple sets) of instructions to perform any one or more of the methodologies described herein.

Computer system 800 may include a computer program product, or software 822, having a non-transitory machine-readable medium having stored thereon instructions, which may be used to program computer system 800 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 800 includes a system processor 802, a main memory 804 (e.g., read-only memory (ROM), flash memory, dynamic random access memory (DRAM) such as synchronous DRAM (SDRAM) or Rambus DRAM (RDRAM), etc.), a static memory 806 (e.g., flash memory, static random access memory (SRAM), etc.), and a secondary memory 818 (e.g., a data storage device), which communicate with each other via a bus 830.

System processor 802 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 802 may also be one or more special-purpose processing devices such as an application specific integrated circuit (ASIC), a field programmable gate array (FPGA), a digital signal system processor (DSP), network system processor, or the like. System processor 802 is configured to execute the processing logic 826 for performing the operations described herein.

The computer system 800 may further include a system network interface device 808 for communicating with other devices or machines. The computer system 800 may also include a video display unit 810 (e.g., a liquid crystal display (LCD), a light emitting diode display (LED), or a cathode ray tube (CRT)), an alphanumeric input device 812 (e.g., a keyboard), a cursor control device 814 (e.g., a mouse), and a signal generation device 816 (e.g., a speaker).

The secondary memory 818 may include a machine-accessible storage medium 831 (or more specifically a computer-readable storage medium) on which is stored one or more sets of instructions (e.g., software 822) embodying any one or more of the methodologies or functions described herein. The software 822 may also reside, completely or at least partially, within the main memory 804 and/or within the system processor 802 during execution thereof by the computer system 800, the main memory 804 and the system processor 802 also constituting machine-readable storage media. The software 822 may further be transmitted or received over a network 861 via the system network interface device 808. In an embodiment, the network interface device 808 may operate using RF coupling, optical coupling, acoustic coupling, or inductive coupling.

While the machine-accessible storage medium 831 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

Thus, embodiments of the present disclosure include processes for treating resist layers with MLD processes.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

What is claimed is:

1. A method, comprising:
treating a resist layer comprising a patterned feature with a chemical vapor deposition (CVD) process that reduces a dimension of the patterned feature, wherein the CVD process comprises flowing a precursor gas into a chamber that infuses into the resist layer; and
transferring the patterned feature into a layer below the resist layer.

2. The method of claim 1, wherein the resist layer comprises a chemically amplified resist (CAR) or a metal oxide resist (MOR).

3. The method of claim 1, wherein the resist layer is tuned to respond to extreme ultraviolet (EUV) radiation, electron-beam patterning, deep ultraviolet (DUV) 193 nm radiation, or 248 nm radiation.

4. The method of claim 1, wherein the patterned feature is a hole through the resist layer, and wherein the dimension is a diameter of the hole.

5. The method of claim 4, wherein the diameter of the hole is less than 25 nm after the MLD process.

6. The method of claim 1, wherein the CVD process is a molecular layer deposition (MLD) process.

7. The method of claim 1, further comprising:
applying a post-treatment to the resist layer after the MLD process, wherein the post-treatment densifies the resist layer, and wherein the post-treatment comprises one or more of a heat treatment, an ion implantation treatment, or a plasma treatment.

8. The method of claim 7, wherein the layer below the resist layer is treated with the CVD process after the resist layer is removed.

9. The method of claim 1, wherein the precursor gas comprises a formula of X₁—R₁—X₂, wherein R₁ is one or more of an alkyl group, an aromatic group, or a cycloalkyl group, wherein X₁ and X₂ are bonded to R₁ in any combination of the structural position, and wherein X₁ and X₂ comprise an amino group, a hydroxide group, an aldehyde group, or an acid group.

10. The method of claim 1, further comprising:
treating the resist layer with a second MLD process, wherein a first precursor gas used in the MLD process is different than a second precursor gas used in the second MLD process.

11. A method, comprising:
treating a resist layer comprising a patterned feature with a molecular layer deposition (MLD) process in a chamber, wherein the MLD process comprises:
(a) supplying a pulse of a precursor gas into the chamber; and
(b) purging the chamber.

12. The method of claim 11, wherein the MLD process comprises cycling operations (a) and (b) a plurality of times.

13. The method of claim 11, wherein a temperature within the chamber during the MLD process is between 20° C. and 150° C.

14. The method of claim 11, wherein a pressure within the chamber during the MLD process is up to 5 Torr.

15. The method of claim 11, wherein a duration of the pulse of the precursor gas is up to 10 seconds.

16. The method of claim 11, wherein the precursor gas comprises a formula of X₁—R₁—X₂, wherein R₁ is one or more of an alkyl group, an aromatic group, or a cycloalkyl group, wherein X₁ and X₂ are bonded to R₁ in any combination of the structural position, and wherein X₁ and X₂ comprise an amino group, a hydroxide group, an aldehyde group, or an acid group.

17. The method of claim 11, wherein the patterned feature is a hole or a line.

18. The method of claim 11, wherein the resist layer is a chemically amplified resist (CAR) that is tuned for reacting to extreme ultraviolet (EUV) radiation, electron-beam patterning, deep ultraviolet (DUV) 193 nm radiation, or 248 nm radiation.

19. A method, comprising:
(a) treating a resist layer comprising a patterned feature with a first molecular layer deposition (MLD) process, wherein the first MLD process comprises a first precursor gas with a formula of X₁—R₁—X₂, wherein R₁ is one or more of an alkyl group, an aromatic group, or a cycloalkyl group, wherein X₁ and X₂ are bonded to R₁ in any combination of the structural position, and wherein X₁ and X₂ comprise an amino group, a hydroxide group, an aldehyde group, or an acid group; and
(b) treating the resist layer with a second MLD process, wherein the second MLD process comprises a second precursor gas with a formula of Y₁—R₂—Y₂, wherein R₂ is one or more of an alkyl group, an aromatic group, or a cycloalkyl group, wherein Y₁ and Y₂ are bonded to R₂ in any combination of the structural position, and wherein Y₁ and Y₂ comprise an acyl chloride group, an isocyanate group, a thiocyanate group, an aldehyde group, an acid group, or a hydroxide group.

20. The method of claim 19, further comprising:
applying a post-treatment to the resist layer between (a) and (b) and/or applying the post-treatment to the resist layer after (b).
